(19) United States
(12) Patent Application Publication
(10) Pub. No.: US 2022/0246585 A1
(43) Pub. Date: Aug. 4, 2022

(54) APPARATUS FOR ILLUMINATION USING LED DIE ARRAY AND METHOD THEREOF

(71) Applicant: IDC KOREA CO., LTD., Suwon-shi (KR)

(72) Inventor: Chang Wook KIM, Hwaseong-shi (KR)

(73) Assignee: IDC KOREA CO., LTD., Suwon-shi (KR)

(21) Appl. No.: 17/621,818

(22) PCT Filed: Jun. 10, 2020
(86) PCT No.: PCT/KR2020/007488

§ 371 Date: Dec. 22, 2021

(30) Foreign Application Priority Data
Aug. 13, 2019 (KR) 10-2019-0098962

(51) Int. Cl. H01L 25/075; H01L 33/50; H01L 33/62; H01L 33/38; H01L 33/00

(52) U.S. Cl. CPC H01L 25/0753; H01L 33/502; H01L 33/62; H01L 2933/0066; H01L 33/005; H01L 2933/0016; H01L 33/38

(57) ABSTRACT

An apparatus for illumination using a light emitting element die array, includes a base sheet; a plurality of light emitting element die array attached to the base sheet and arranged in a matrix shape, the light emitting element including a light emitting surface and an electrode formation surface facing the light emitting surface, flip chip bonding electrodes being formed on the electrode formation surface; and a transparent support layer covering the light emitting surface of the plurality of light emitting element dies, and fixing the plurality of light element dies by a constant light source interval, the transparent support layer including a fluorescent material absorbing light emitting through the light emitting surface to change a wavelength of the light.

### TECHNICAL FIELD

The disclosure relates to an apparatus for illumination using a light emitting element die array and a method thereof, and more particularly, to an apparatus for illumination using a light emitting element die array and a method thereof, which directly uses light emitting element (LED) dies of a wafer level without classification of good/bad to manufacture a light source module, thereby decreasing manufacturing cost.

### BACKGROUND ART

A light emitting element such as a light emitting diode (LED) is one of semiconductor elements transforming electric energy into light, and highlighted as a light source of next generation to replace conventional fluorescent lamps, incandescent lamps, or the like.

Since the light emitting diode generates light using an electric potential gap of a semiconductor element, the light emitting diode has eco-friend characteristics such as a longer lifetime than the conventional light sources, rapid response speed, and low power consumption. Thus, various researches for replacing the conventional light sources with the light emitting diodes have been conducted, and the light emitting diodes are used as the light sources for illumination such as various indoor/outdoor lamps, liquid crystal displays, billboards, street lamps, headlights, or the like.

Recently, in field of a flexible display, a display technology using micro LEDs, which are light emitting diodes having chips manufactured in a micrometer size, has been developed.

The micro LEDs are classified into mini LEDs and micro LEDs by a die size thereof. The mini LEDs have a short side of about 100 μm and a long side of about 200 μm. The micro LEDs have a size of 10˜100 μm. That is, the micro LEDs have a size smaller than 100 μm. The mini LEDs and the micro LEDs are manufactured in the micrometer size, and have benefits of flexibility, greater size and longer lifetime than an OLED, lower power consumption, and high luminance to be visible under bright light such as sunlight. In particular, the micro LEDs have lower power consumption than the OLED by 5 times to 10 times, and can be applied to manufacture a large sized display more than 100 inches.

However, the length of conventional micro LEDs is 30 micrometers, which is smaller than LED chips (about 300 μm) used in a conventional display. The conventional micro LEDs have a smaller length of one tenth and size of one hundredth than the conventional display. Thus, chips are not easily separated from a wafer, and packaging (attaching on substrate and connecting electrode) the chips takes a long time. By an arithmetic calculation, a new manufacturing apparatus faster than a conventional manufacturing apparatus by one hundred times or one hundred conventional manufacturing apparatuses are required to manufacture the micro LEDs using the conventional method for manufacturing the LEDs. Thus, the cost of attaching hundreds of thousands to millions of the LED chips is increased.

Among conventional methods of manufacturing the micro LEDs, an LED layer is formed on a sapphire substrate. A precise transfer technology for precisely and rapidly transporting millions of micro LED chips to a flexible substrate or a plane substrate is required. Nobody has developed an apparatus for illumination based on inorganic GaN and commercialized the transfer technology.

### DISCLOSURE

### Technical Problem

Aspects of the invention provide an apparatus for illumination using a light emitting element die array and a method thereof, which directly uses light emitting element (LED) dies of a wafer level without classification of good/bad to manufacture a light source module, thereby decreasing manufacturing cost.

Aspects of the invention provide a method of manufacturing an apparatus for illumination using a light emitting element die array, which is capable of manufacturing high power light emitting elements of tens of voltages at a low cost.

### Technical Solution

According to an embodiment of the disclosure, an apparatus for illumination using a light emitting element die array, includes a base sheet; a plurality of light emitting element die array attached to the base sheet and arranged in a matrix shape, the light emitting element including a light emitting surface and an electrode formation surface facing the light emitting surface, flip chip bonding electrodes being formed on the electrode formation surface; and a transparent support layer covering the light emitting surface of the plurality of light emitting element dies, and fixing the plurality of light element dies by a constant light source interval, the transparent support layer including a fluorescent material absorbing light emitting through the light emitting surface to change a wavelength of the light.

A substrate for illumination may be prepared instead of the base sheet. A circuit pattern electrically connecting the plurality of light emitting element dies in serial-parallel may be formed on the substrate for illumination, and connected to a flip chip electrode of the electrode formation surface.

The apparatus for illumination using the light emitting element die may further include a molding member that molds an edge portion between the substrate for illumination and the transparent support layer.

The base sheet may be a transfer film on which the plurality of light emitting element dies are directly transferred in a wafer level, and the transfer film may be expanded by the constant light source interval from a die separation interval of the wafer level.

A micro lens array may further be formed on another surface of the transparent support layer, which face a surface attaching the dies.

The plurality of light emitting element dies may further include more than at least one redundancy light emitting element die, and the substrate for illumination may further include a redundancy circuit replacing a bad light emitting element die into the redundancy light emitting element die.

According to an embodiment of the disclosure, a method of manufacturing an apparatus for illumination using a light emitting element die array, includes preparing a base sheet, on which electrode formation surfaces of a plurality of light emitting element dies are attached; extending the base sheet to extend the plurality of light emitting element dies from a die separation interval to a constant light source interval; and covering light emitting surfaces of the plurality of light emitting element dies by a transparent support layer including a fluorescent material while the base sheet is extended.

The preparing of the base sheet may further comprise preparing a substrate for illumination, on which a plurality of bonding pads arranged in the constant light source intervals is formed. The method of manufacturing the apparatus for illumination using the light emitting element die array may further include after covering the light emitting surfaces by the transparent support layer, flip-chip bonding the plurality of fixed light emitting element dies on the substrate for illumination; and molding an edge portion between the substrate for illumination and the transparent support layer.

The method of manufacturing the apparatus for illumination using the light emitting element die array may further include after the flip-chip bonding, testing the plurality of light emitting element dies fixed by the transparent support layer; and repairing by replacing a bad light emitting element by a redundancy light emitting element based on the test result.

### Advantageous Effects

According to the above-described apparatus for illumination using the light emitting element die array directly uses the light emitting element (LED) die array of a wafer level without classification of good/bad to manufacture the apparatus for illumination, and a test process for classifying millions of microchips may be omitted. Thus, a manufacturing cost thereof may be decreased. Also, tens of to hundreds of light emitting dies are collectively transferred on a substrate for illumination, and a manufacturing cost is readily decreased. Thus, a high power LED illumination apparatus may be manufactured.

However, the effects of the disclosure are not limited to the aforementioned effects, and various other effects, which are not mentioned above, are included in the specification by those skilled in the art.

### BRIEF DESCRIPTION OF THE DRAWINGS

FIG. 1 is a view illustrating a light source module of an apparatus for illumination using a light emitting element die array according to an embodiment.

FIG. 2 is a view illustrating a substrate for illumination combined with a light source module of an apparatus for illumination using a light emitting element die array according to an embodiment.

FIG. 3 is a view illustrating a arranged state of light emitting element dies 114 arranged by a microchip separation interval of a wafer level according to an embodiment.

FIG. 4 is a view illustrating an arranged state of the light emitting element dies 114 of FIG. 3 extended by an illumination interval.

FIG. 5 is a plan view illustrating an apparatus for illumination using a light emitting element die array according to an embodiment.

FIG. 6 is an equivalent circuit diagram of 4*5 group of the apparatus for illumination of FIG. 5.

FIG. 7 is a flow chart illustrating a method of manufacturing an apparatus for illumination using light emitting element dies according to an embodiment.

### BEST MODE FOR PRACTING INVENTION

Regarding the example embodiments of the present invention disclosed in the specification, specific structural or functional explanations are only illustrated for the purpose of explaining the example embodiments of the present invention, and the example embodiments of the present invention may be enforced in various shapes, and should not be interpreted by limiting the example embodiments of the present invention disclosed in the specification.

The present invention may be embodied in various alternative forms and may have various shapes, and thus, specific example embodiments are illustrated in drawings and are explained in the specification. However, the specification should not be construed as limited to the example embodiments set forth herein, and the specification should be understood to include all variations, modifications or alternative forms included in the spirit and scope of the present invention. In describing each drawing, like numerals are used for like elements.

Throughout this specification, it will be understood that when a portion is “connected to” or “coupled to” another portion, the portion may be directly connected to or directly coupled to another portion, also, it may be understood to include the portion may be “indirectly connected to” another portion with intervening an element between the portions. However, when a portion is described to be “directly connected to” or “directly coupled to” another portion, another portion is not interposed between the portions. Other expressions explaining relationship between portions such as “between”, “directly between”, “adjacent to”, “directly adjacent to”, etc., should be explained in the same way.

The terms used in the present invention is only used to describe particular embodiments, and it is not intended to limit the present invention. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, best modes of the present invention will be described in detail with reference to the accompanying drawings. In numbering reference numerals to the structural parts of each drawing, like numerals may refer to like elements throughout the description of the figures although the reference numerals are displayed in different drawings.

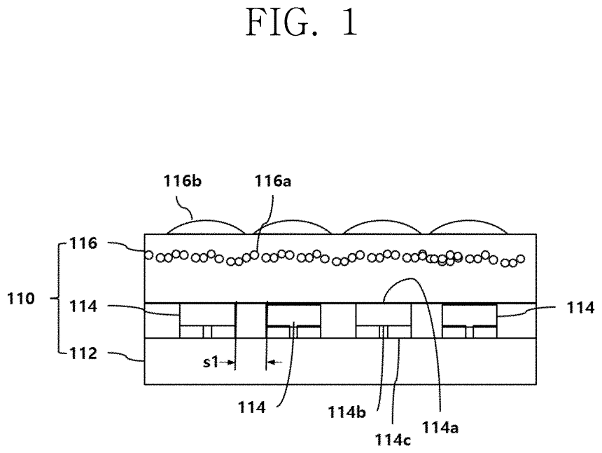

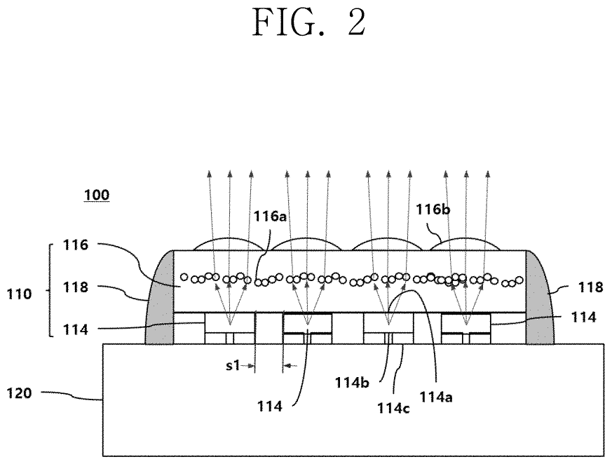

FIG. 1 is a view illustrating a light source module of an apparatus for illumination using a light emitting element die array according to an embodiment. FIG. 2 is a view illustrating a substrate for illumination combined with a light source module of an apparatus for illumination using a light emitting element die array according to an embodiment.

Referring to the drawings, a light source module 110 of the apparatus 100 for illumination using a light emitting element die array includes a base sheet 112, a plurality of light emitting element dies 114, and a transparent support layer 116.

In the disclosure, the base sheet 112 may be a transfer film on which the plurality of light emitting element dies 114 are directly transferred in a wafer level or an exclusive film of arranging illumination and having improved extension characteristics. The base sheet 112 may be good extension characteristics and expanded by a fixed constant interval from a die separation interval of the wafer level. The base sheet 112 for supplying a current, to the plurality of light emitting element dies 114 may be removed and substituted by a substrate 120 for illumination.

Each of the plurality of light emitting element dies 114 may include a light emitting surface 114a, an electrode formation surface 114b facing the light emitting surface 114a and having flip chip bonding electrodes 114c thereon. The electrode formation surface 114b is attached to the base sheet 112, and the plurality of light emitting element dies 114 are arranged in a matrix shape.

Each of the light emitting element dies 114 is an LED light source having a size of micrometer size. For example, each of the light emitting element dies 114 may include mini LEDs having a short side of about 100 μm and a long side of about 200 μm or micro LEDs having a size of 10˜100 μm. The light emitting element dies 114 selectively emit light having a wavelength range from an ultraviolet light to an infrared light. The light emitting element dies 114 may include an ultra violet (UV) LED chip, a green LED chip, a blue LED chip, or a red LED chip, an infrared LED chip. The light emitting element dies 114 may have a thickness of more than 10 μm. For example, the thickness of the light emitting element dies 114 may in a range of 10 μm to 100 μm. The light emitting element dies 114 may have different thicknesses based on a horizontal type chip or a vertical type chip. In the embodiment the light emitting element dies 114 may be flip chips. The light emitting element dies 114 may have a polygonal shape such as a square shape or a rectangular shape and a circular shape in a plan view. The light emitting element dies 114 may include a light emitting structure and an electrode layer. The light emitting structure may include a semiconductor layer of a first conductive type, an active layer, and a second conductive type semiconductor layer. The light emitting structure may selectively emit light having a wavelength in a range of the ultraviolet light to the infrared light. The light emitting structure may include III group-V group compound semiconductor and II group-VI group compound semiconductor. The electrode layer is electrically connected to a first lead electrode and supply an electric power. An electrode of the light emitting structure may not use a wire bonding type, but connected by a PCB pattern or ITO in serial-parallel. The electrode layer may be implemented with a single layer or multiple layers, but the disclosure is not limited thereto. The light emitting element dies 114 may be arranged in at least one column or row, or arranged in two column and/or more than two columns. In case that the plurality of light emitting element dies 114 are arranged, the light emitting element dies 114 may be separated from each other by a constant interval. The light emitting element dies 114 may be separated by a constant interval or different intervals.

The transparent support layer 116 covers the light emitting surface 114a of the plurality of light emitting element dies 114 and fixes them by a constant light source interval s1 (not illustrated). The transparent support layer 116 may include a fluorescent material 116a absorbing the light emitting through the light emitting surface 114a and changing a wavelength of the absorbed light. The fluorescent material 116a absorbs a portion of the light emitted from the light emitting element die 114 and change wavelength of the absorbed light. The fluorescent material may include at least one of a yellow fluorescent material, a green fluorescent material, a blue fluorescent material, and a red fluorescent material. For example, the fluorescent material may include at least one of a nitride based fluorescent material, which is activated by lanthanoid based material such as Eu, Ce, etc., an oxy-nitride based fluorescent material, a sialon based fluorescent material, lanthanide based such as Eu etc., an alkaline earth halogen apatite fluorescent material, which is activated by a transition metal based such as Mn, etc., an alkali earth metal boric acid halogen fluorescent material, an alkali earth aluminate fluorescent material, alkali earth silicate, alkali earth sulfides, alkali earth thiogallate, alkali earth silicon nitride, germinate, or rear earth aluminate, which is mainly activated by lanthanide based material such as Ce, etc., organic or organic complex, which is mainly activated by a rear earth silicate or lanthanide based material such as Eu, etc. In particular, the disclosure is not limited by the fluorescent material. The light emitted from the fluorescent material 116a and light emitted from the die 114 may be mixed to be light. The white light may have a color temperature in a range of 2,000 K to 15,000 K. The white light may have at least one color temperature of a warm white, a cool white, of a neutral white.

The transparent support layer 116 of the embodiment may use a glass or a heat resistance polymer film, which resists thermal deformation of a high temperature in a SMT process. Also, an adhesive (Si, etc.) or a semi-solidified adhesive film may be used on a surface of the transparent support layer 116 to attach the plurality of light emitting element dies 114. Also, a micro lens array 116b may further be formed on another surface of the transparent support layer 116, which face the surface attaching the dies 114. The micro lens array 116b may not be respectively correspond to the dies 114 in an illumination purpose, which is different from a display device. The micro lens array 116b may condense or diffuse the emitting light in a desired direction.

Referring to FIG. 2, the substrate 120 for illumination, which substitute the base sheet 112, is further be prepared in the embodiment, and a circuit pattern connected to the flip chip bonding electrode 114c of the electrode formation surface 114b to connect the plurality of light emitting element dies 114 in serial-parallel is formed on the substrate 120 for illumination.

Also, a molding member 118 that molds an edge portion between the substrate 120 for illumination and the transparent support layer 116 may further be prepared to increase mechanical strength thereof. For example, the molding member 118 may be silicon or epoxy molding compound.

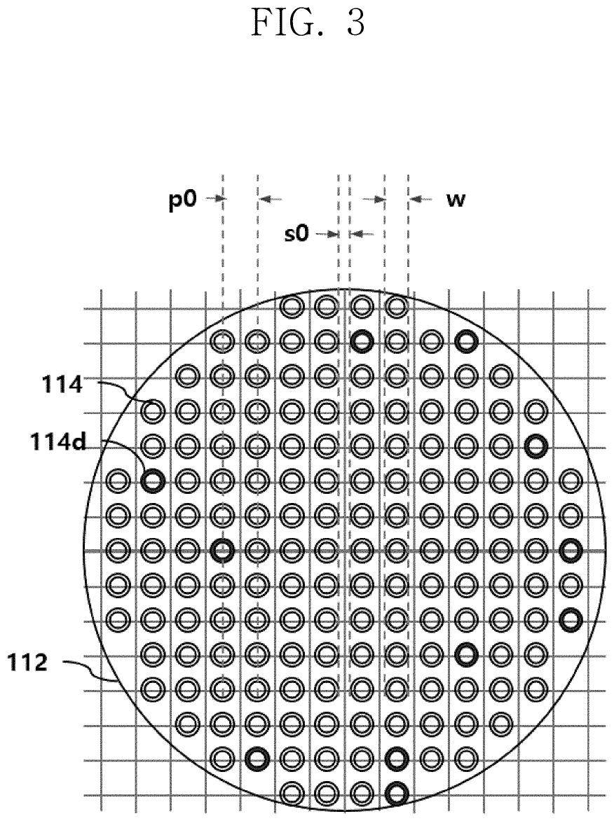

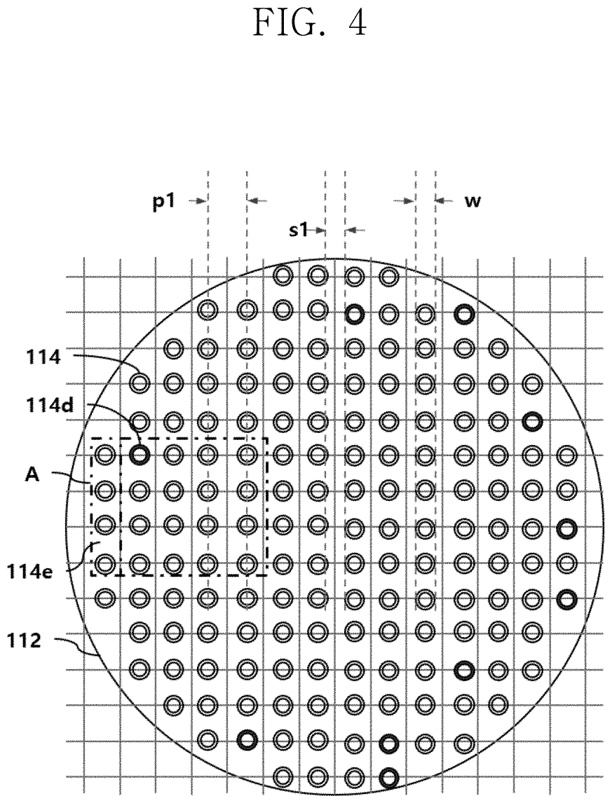

FIG. 3 is a view illustrating a arranged state of light emitting element dies 114 arranged by a microchip separation interval of a wafer level according to an embodiment. FIG. 4 is a view illustrating an arranged state of the light emitting element dies 114 of FIG. 3 extended by an illumination interval.

Referring to drawings, the light emitting element dies 114 are arranged on the wafer by a pitch P0 having an element width w and a separation interval s0 on a wafer. The light emitting element dies 114 are transferred on the base sheet 112 by the above-described arrangement. The base sheet 112, on which the light emitting element dies 114 are transferred, is mounted on an extension zig, and extended in various directions as shown in FIG. 4. By the extension, the light emitting element dies 114 are rearranged by a pitch p1 having an element width w and an interval s1 for illumination. The light emitting element dies 114, which are rearranged by the interval s1 for illumination, are separated in a group size as shown in portion A (illustrated by dash-dotted line) of FIG. 4, and used as the light source module A for illumination.

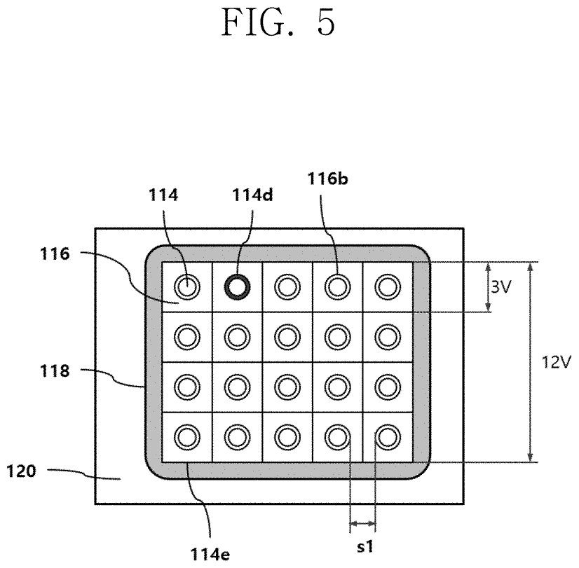

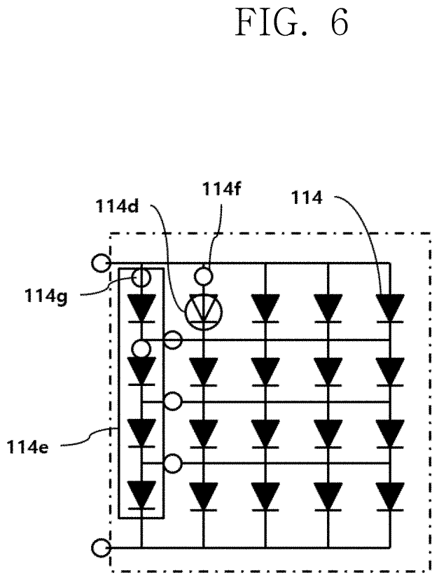

FIG. 5 is a plan view illustrating an apparatus for illumination using a light emitting element die array according to an embodiment. FIG. 6 is an equivalent circuit diagram of 4*5 group of the apparatus for illumination of FIG. 5.

Referring to the drawings, since bad dies 114d may be included during separating dies to 4*4 group, the dies may be grouped in 5*4 groups, which includes a redundancy column 114e for replacing the bad die into a redundancy die. The redundancy replacing technology may use electric fusing or laser fusing technology. Further redundancy column or both of redundancy column and redundancy row may be included instead of the redundancy column.

Referring to FIG. 6, all the dies of 4*5 group are connected in serial-parallel. The bad die 114d may be replaced to a good die by the electric fusing or laser fusing technology. In the drawings, the reference character 114f represents an opened state, in which a circuit connection is opened by a fusing, and the reference character 114g represents a connected state. By the redundancy repair process, the bad light emitting element may be replaced by a normal redundancy light emitting element. Thus, each of the light emitting elements may be fabricated as a high power light source having a voltage of 3V*4=12V between terminals of each of the light emitting elements. In an embodiment, for convenience of explanation, 12V is described. However, the high power light source may be manufactured to have 18V, 24V, 36V, or the like by serial connection of the light emitting elements.

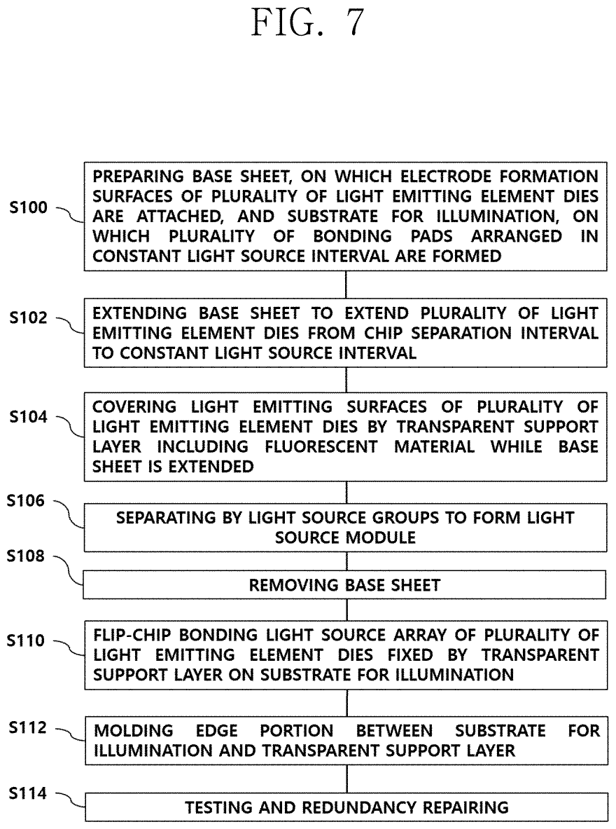

FIG. 7 is a flow chart illustrating a method of manufacturing an apparatus for illumination using light emitting element dies according to an embodiment.

Referring to the drawings, firstly a base sheet 112, on which electrode formation surfaces of the plurality of light emitting element dies 114 are attached, is prepared (S100). The base sheet 112 may be a transfer film on which the plurality of light emitting dies 114 are transferred from the wafer by a chip separation interval. The substrate 120 for illumination, on which a plurality of bonding pads are arranged in a constant light source intervals is formed, is prepared. For example, an AlN substrate having excellent heat radiation characteristics may be used as the substrate 120 for illumination.

Then, the base sheet is mounted on the extension zig and extended to the light source interval to extend the plurality of light emitting element dies 114 from the chip separation interval to the constant light source interval of the substrate for illumination (S102). In the extension process, the extension may be performed at a proper temperature in an extension chamber.

Then, while the base sheet 112 is extended, the light emitting surfaces of the plurality of light emitting element dies 114 is covered by the transparent support layer 116 including the fluorescent material, and the light source interval is fixed and supported (S104). The transparent support layer 116 is formed by coating and hardening a polymer slurry mixed by a polymer resin and a latent hardener as a solvent and forming a semi solidified resin film. Then, fluorescent powder is provided on the semi solidified resin film, and UV light is irradiated to completely solidify. Then, a lens film, on which micro lens are formed, is applied to complete the transparent support layer 116. Thus, in case that the transparent support layer 116 is completed, the light emitting element dies 114 are fixed and supported by the light source interval.

Then, they are separated by light source groups of illumination to form the separated light source module A (S106).

In order to fabricate the apparatus for illumination, the base sheet 112 of the light source module A is removed (S108).

Then, the plurality of light emitting element dies 114 fixed on the transparent support layer 116 are flip-chip bonded on the substrate 120 for illumination (S110).

After the flip-chip bonding, an edge portion between the substrate 120 for illumination and the transparent support layer 116 is molded by the molding member 118 (S112).

After the flip-chip bonding, the plurality of light emitting element dies fixed by the transparent support layer are tested, and bad light emitting element is replaced to be repaired by the redundancy light emitting element based on the test result (S114).

According to the above-described method of manufacturing the apparatus for illumination by the groups of the light emitting element dies, the plurality of dies of the wafer level are directly and simultaneously transferred on the substrate for illumination without a good/bad test process to manufacture the light source for illumination. Thus, complex processes of testing, classifying good/bad, rearranging good elements, etc., may be removed, and manufacturing cost may be greatly decreased. Manufacturing time is decreased to improve productivity, and the method of manufacturing the apparatus for illumination is economic. Since the good/bad test is omitted, small number of bad dies may be included. However, in the apparatus for illumination which is different from a display, luminance change smaller than 10% may be acceptable. In a field requiring precise luminance, luminance may be precisely set by the redundancy technology.

As described above, although preferable embodiments of the disclosure have been described, those skilled in the art will readily appreciate that many modifications are possible in the example embodiments without materially departing from the novel teachings and advantages of the inventive concept.

What is claimed is:

1. An apparatus for illumination using a light emitting element die array, comprising:
a base sheet;
a plurality of light emitting element die array attached to the base sheet and arranged in a matrix shape, the light emitting element including:
a light emitting surface; and
an electrode formation surface facing the light emitting surface, flip chip bonding electrodes being formed on the electrode formation surface; and
a transparent support layer covering the light emitting surface of the plurality of light emitting element dies, and fixing the plurality of light element dies by a constant light source interval, the transparent support layer including a fluorescent material absorbing light emitting through the light emitting surface to change a wavelength of the light.

2. The apparatus for illumination using the light emitting element die array of claim 1, further comprising a substrate for illumination instead of the base sheet, wherein a circuit pattern electrically connecting the plurality of light emitting element dies in serial-parallel is formed on the substrate for illumination, and is connected to a flip chip bonding electrode of the electrode formation surface.

3. The apparatus for illumination using the light emitting element die array of claim 2, further comprising a molding member that molds an edge portion between the substrate for illumination and the transparent support layer.

4. The apparatus for illumination using the light emitting element die array of claim 1, wherein the base sheet is a transfer film on which the plurality of light emitting element dies are directly transferred in a wafer level, and the transfer film is expanded by the constant light source interval from a die separation interval of the wafer level.

5. The apparatus for illumination using the light emitting element die array of claim 1, wherein a micro lens array is further formed on another surface of the transparent support layer, which face a surface attaching the dies.

6. The apparatus for illumination using the light emitting element die array of claim 2, wherein the plurality of light emitting element dies further include more than at least one redundancy light emitting element die, and the substrate for illumination further includes a redundancy circuit replacing a bad light emitting element die into the redundancy light emitting element die.

7. A method of manufacturing an apparatus for illumination using a light emitting element die array, comprising:
preparing a base sheet, on which electrode formation surfaces of a plurality of light emitting element dies are attached;
extending the base sheet to extend the plurality of light emitting element dies from a die separation interval to a constant light source interval; and
covering light emitting surfaces of the plurality of light emitting element dies by a transparent support layer including a fluorescent material while the base sheet is extended.

8. The method of manufacturing the apparatus for illumination using the light emitting element die array of claim 7, wherein
the preparing of the base sheet further comprises preparing a substrate for illumination, on which a plurality of bonding pads arranged in the constant light source interval is formed,
the method further comprising:
after covering the light emitting surfaces by the transparent support layer, flip-chip bonding the plurality of fixed light emitting element dies on the substrate for illumination; and
molding an edge portion between the substrate for illumination and the transparent support layer.

9. The method of manufacturing the apparatus for illumination using the light emitting element die array of claim 8, further comprising:
after the flip-chip bonding, testing the plurality of light emitting element dies fixed by the transparent support layer; and
repairing by replacing a bad light emitting element by a redundancy light emitting element based on the test result.
